(19) United States
(12) Patent Application Publication
(10) Pub. No.: US 2025/0239453 A1
(43) Pub. Date: Jul. 24, 2025

(54) METHOD FOR PROCESSING WORKPIECE

(71) Applicant: DISCO CORPORATION, Tokyo (JP)

(72) Inventor: Kensuke FURUTA, Tokyo (JP)

(21) Appl. No.: 19/010,530

(22) Filed: Jan. 6, 2025

(30) Foreign Application Priority Data
Jan. 18, 2024 (JP) 2024-006184

(51) Int. Cl. H01L 21/304; H01L 21/3065; H01L 21/78

(52) U.S. Cl. CPC H01L 21/304; H01L 21/3065; H01L 21/78

(57) ABSTRACT

A method is for processing a workpiece obtained by bonding one surface of a wafer and one surface of a support wafer via a bonding layer. The method includes: trimming the workpiece, the trimming including removing a peripheral edge portion of the wafer of the workpiece in a thickness direction and removing a part of a peripheral edge portion of the one surface of the support wafer in the thickness direction; after trimming the workpiece, forming a protective film on the peripheral edge of the one surface of the support wafer exposed by trimming the workpiece; and etching the workpiece on a wafer side after forming the protective film.

### CROSS-REFERENCE TO RELATED APPLICATION(S)

The present application claims priority to and incorporates by reference the entire contents of Japanese Patent Application No. 2024-006184 filed in Japan on Jan. 18, 2024.

### BACKGROUND OF THE INVENTION

The present disclosure relates to a method for processing a workpiece obtained by bonding one surface of a wafer and one surface of a support wafer via a bonding layer.

In recent years, the use of wafer stacks (workpieces) in each of which a wafer is bonded onto a support wafer via a bonding layer has increased. Before the wafer stack is thinned by grinding the wafer stack on a wafer side, the wafer may be trimmed in a circular shape so that a sharp edge is not formed on the wafer after the wafer stack is trimmed (see, for example, JP 2017-092413 A).

However, in the method described in JP 2017-092413 A and the like, when trimming is performed, due to processing accuracy issues or the like, not only is the upper wafer trimmed, but the lower support wafer may also be trimmed to a certain depth in the thickness direction. In such a case, when etching is further performed on the wafer side for the purpose of removing processing damage after performing grinding processing on the wafer side, the peripheral edge portion of the support wafer exposed by performing trimming is also etched.

When a device is formed on a bonding layer side of the support wafer, there is a problem that the device on the support wafer is damaged by etching the peripheral edge portion.

Therefore, in processing a wafer stack (workpiece) obtained by bonding a wafer onto a support wafer via a bonding layer, it is required that a peripheral edge portion of the support wafer exposed by trimming should not be etched.

### SUMMARY

A method according to one aspect of the present disclosure is for processing a workpiece obtained by bonding one surface of a wafer and one surface of a support wafer via a bonding layer. The method includes: trimming the workpiece, the trimming including removing a peripheral edge portion of the wafer of the workpiece in a thickness direction and removing a part of a peripheral edge portion of the one surface of the support wafer in the thickness direction; after trimming the workpiece, forming a protective film on the peripheral edge of the one surface of the support wafer exposed by trimming the workpiece; and etching the workpiece on a wafer side after forming the protective film.

### BRIEF DESCRIPTION OF THE DRAWINGS

FIG. 1 is a perspective view schematically illustrating an example of a configuration of a workpiece to be processed by a method for processing a workpiece according to an embodiment;

FIG. 2 is a cross-sectional view schematically illustrating the workpiece illustrated in FIG. 1;

FIG. 3 is a flowchart illustrating a flow of the method for processing a workpiece according to the embodiment;

FIG. 4 is a side view schematically illustrating a trimming step of the method for processing a workpiece illustrated in FIG. 3 in a partial cross section;

FIG. 5 is a cross-sectional view schematically illustrating the workpiece after the trimming step of the method for processing a workpiece illustrated in FIG. 3;

FIG. 6 is a side view schematically illustrating a flattening step of the method for processing a workpiece illustrated in FIG. 3 in a partial cross section;

FIG. 7 is a cross-sectional view schematically illustrating a modification of the flattening step illustrated in FIG. 6 in a partial cross section;

FIG. 8 is a side view schematically illustrating a protective film forming step of the method for processing a workpiece illustrated in FIG. 3 in a partial cross section;

FIG. 9 is a cross-sectional view schematically illustrating the workpiece after the protective film forming step of the method for processing a workpiece illustrated in FIG. 3;

FIG. 10 is a side view schematically illustrating a grinding step of the method for processing a workpiece illustrated in FIG. 3 in a partial cross section;

FIG. 11 is a cross-sectional view schematically illustrating the workpiece after the grinding step of the method for processing a workpiece illustrated in FIG. 3;

FIG. 12 is a side view schematically illustrating an etching step of the method for processing a workpiece illustrated in FIG. 3 in a partial cross section; and

FIG. 13 is a cross-sectional view schematically illustrating the workpiece after the etching step of the method for processing a workpiece illustrated in FIG. 3.

### DETAILED DESCRIPTION OF THE PREFERRED EMBODIMENTS

An embodiment of the present disclosure will be described in detail with reference to the drawings. The present invention is not limited by the contents described in the following embodiment. In addition, the constituent elements described below include those that can be easily conceived by those skilled in the art and those that are substantially the same. Furthermore, the configurations described below can be appropriately combined. In addition, various omissions, substitutions, or changes can be made to the configurations without departing from the scope and spirits of the present invention.

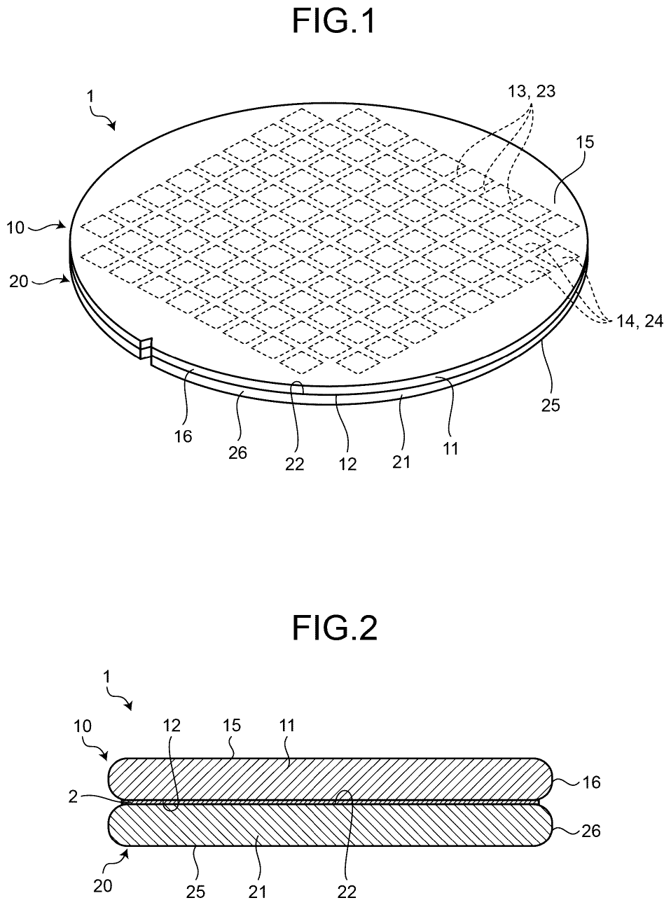

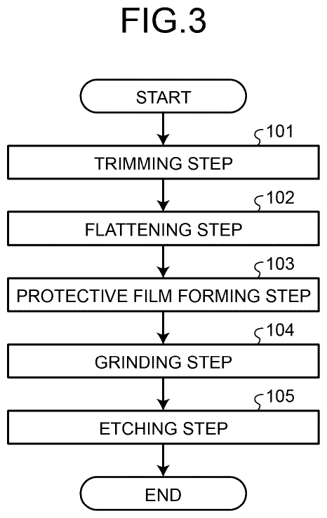

A method for processing a workpiece according to an embodiment of the present invention will be described with reference to the drawings. FIG. 1 is a perspective view schematically illustrating an example of a configuration of a workpiece to be processed by the method for processing a workpiece according to the embodiment. FIG. 2 is a cross-sectional view schematically illustrating the workpiece illustrated in FIG. 1. FIG. 3 is a flowchart illustrating a flow of the method for processing a workpiece according to the embodiment.

### Workpiece

The method for processing a workpiece according to the embodiment is a method for processing a workpiece 1 illustrated in FIG. 1. In the embodiment, the workpiece 1 to be processed by the method for processing a workpiece includes a wafer 10 and a support wafer 20. In the embodiment, the wafer 10 and the support wafer 20 are wafers such as disk-shaped semiconductor wafers using silicon, gallium arsenide, silicon carbide (SiC), or the like as substrates 11 and 21. In the embodiment, the wafer 10 and the support wafer 20 have the same configuration.

As illustrated in FIG. 1, in the wafer 10 and the support wafer 20, a plurality of planned division lines 13 and 23 intersecting (in the embodiment, perpendicular to) each other are set on front surfaces 12 and 22 (each corresponding to one surface), and devices 14 and 24 are formed in a plurality of regions partitioned by the planned division lines 13 and 23. The devices 14 and 24 are, for example, integrated circuits such as integrated circuits (ICs) or large scale integrations (LSIs), or various types of memories (semiconductor storage devices).

The workpiece 1 is configured by bonding the front surface 12 of the wafer 10 and the front surface 22 of the support wafer 20. In the embodiment, as illustrated in FIG. 2, in the workpiece 1, the front surface 12 of the wafer 10 and the front surface 22 of the support wafer 20 are bonded to each other via a bonding layer 2 made of a resin adhesive, an oxide film (SiO2), or the like. The workpiece 1 is individualized into separate device chips having a so-called three-dimensional stack structure by dividing the wafers 10 and 20 along the planned division lines 13 and 23. In the present invention, the bonding layer 2 may be a bonding layer that bonds the front surfaces 12 and 22 to each other by performing surface activation treatment.

In the embodiment, the wafer 10 and the support wafer 20 have chamfered portions 16 and 26 formed in peripheral edge portions thereof. The chamfered portions 16 and 26 are continuous with the front surfaces 12 and 22 and back surfaces 15 and 25 (each corresponding to the other surface) on the opposite sides of the front surfaces 12 and 22. The front surfaces 12 and 22 and back surfaces 15 and 25 are parallel to each other and each are flat. The chamfered portions 16 and 26 are formed from the front surfaces 12 and 22 to the back surfaces 15 and 25, and are formed to each have an arcuate cross section such that the center in the thickness direction is located on the outermost peripheral side.

Thus, in the embodiment, the outer peripheral edges of the wafer 10 and the support wafer 20 are chamfered in an arc shape by providing the chamfered portions 16 and 26. In the embodiment, the workpiece 1 is a wafer stack formed by bonding the wafer 10 and the support wafer 20 to each other. In the embodiment, in the workpiece 1, the wafer 10 and the support wafer 20 are formed to have the same diameter, and the wafer 10 and the support wafer 20 are coaxially arranged. In the embodiment, in the wafers 10 and 20, the substrates 11 and 21 are made of silicon, and have an outer diameter of 300 mm and a thickness of 775 μm. In the embodiment, the bonding layer 2 is made of an oxide film (SiO2), and has a thickness of 1 μm or more and 10 μm or less.

### Method for Processing Workpiece

The method for processing a workpiece according to the embodiment is a method for processing a workpiece 1 illustrated in FIGS. 1 and 2, and includes removing the chamfered portion 16 in the peripheral edge portion of the wafer 10 and, thereafter, thinning the wafer 10 to a predetermined thickness. As illustrated in FIG. 3, the method for processing a workpiece according to the embodiment includes a trimming step 101, a flattening step 102, a protective film forming step 103, a grinding step 104, and an etching step 105.

### Trimming Step

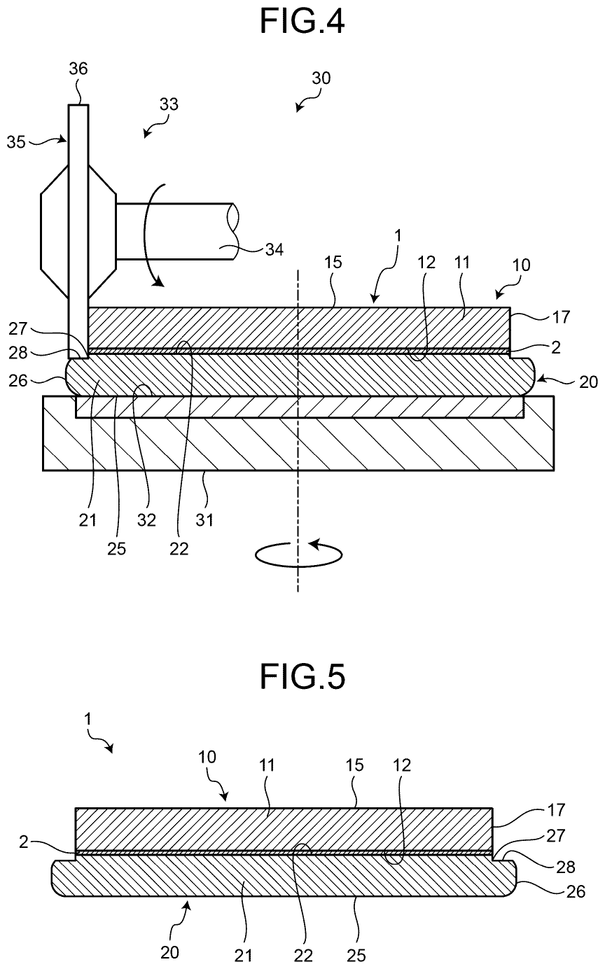

FIG. 4 is a side view schematically illustrating the trimming step of the method for processing a workpiece illustrated in FIG. 3 in a partial cross section. FIG. 5 is a cross-sectional view schematically illustrating the workpiece after the trimming step of the method for processing a workpiece illustrated in FIG. 3. The trimming step 101 is a step of trimming the workpiece. The trimming step includes removing the peripheral edge portion of the wafer 10 of the workpiece 1 in the thickness direction and removing a part of the peripheral edge portion on the front surface 22 side of the support wafer 20 in the thickness direction.

In the embodiment, in the trimming step 101, a processing device 30 illustrated in FIG. 4 sucks and holds the back surface 25 of the support wafer 20 of the workpiece 1 on a holding surface 32 of a holding table 31. In the embodiment, in the trimming step 101, as illustrated in FIG. 4, the processing device 30 causes an annular cutting edge 36 of a cutting blade 35, which is rotated by a spindle 34 of a processing unit 33 about an axis parallel to the holding surface 32, to cut into the peripheral edge portion of the wafer 10 until it reaches the peripheral edge portion of the support wafer 20, and rotates the holding table 31 at least once about an axis perpendicular to the holding surface 32.

In this manner, in the embodiment, in the trimming step 101, (i) the cutting blade 35 is caused to cut into the peripheral edge portion of the wafer 10 as illustrated in FIG. 4, (ii) the peripheral edge portion of the wafer 10 of the workpiece 1 is removed entirely in the thickness direction to remove the entire chamfered portion 16, and (iii) a part of the peripheral edge portion of the support wafer 20 is removed from the front surface 22 side to remove a part of the chamfered portion 26 from the front surface 22 side to remove a part of the peripheral edge portion of the support wafer 20 on the front surface 22 side in the thickness direction, as illustrated in FIG. 5. In the embodiment, in the trimming step 101, an outer side surface 17 (corresponding to a side surface) of the wafer 10 of the workpiece 1 is formed flat along a direction perpendicular to both the front surface 12 and the back surface 15 in a cross section passing through the axis. In the embodiment, in the trimming step 101, as illustrated in FIG. 5, an outer side surface 27 formed on the same plane as the outer side surface 17 is formed on the front surface 22 side of the peripheral edge portion of the support wafer 20 of the workpiece 1, and a stepped surface 28 formed in parallel to both the front surface 22 and the back surface 25 is formed from the outer side surface 27 to the outer edge of the support wafer 20.

### Flattening Step

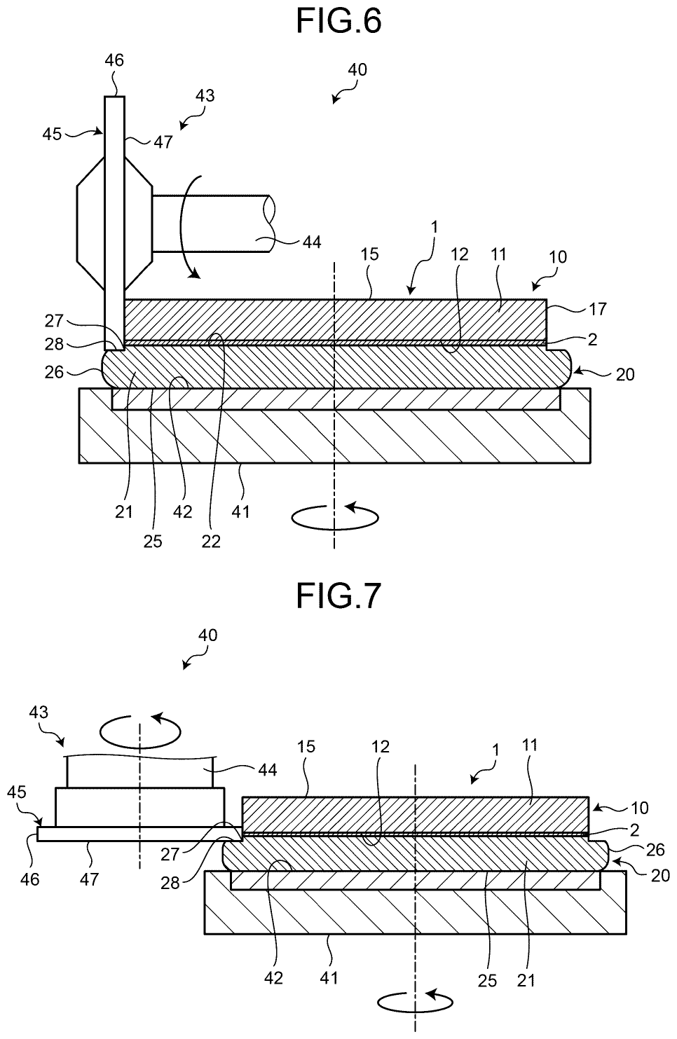

FIG. 6 is a side view schematically illustrating the flattening step of the method for processing a workpiece illustrated in FIG. 3 in a partial cross section. FIG. 7 is a cross-sectional view schematically illustrating a modification of the flattening step illustrated in FIG. 6 in a partial cross section. The flattening step 102 is a step of flattening the peripheral edge portion of the front surface 22 of the support wafer 20 exposed by the trimming step 101 before the protective film forming step 103.

In the embodiment, in the flattening step 102, a processing device 40 illustrated in FIG. 6 sucks and holds the back surface 25 of the support wafer 20 of the workpiece 1 on a holding surface 42 of a holding table 41. In the embodiment, in the flattening step 102, as illustrated in FIG. 6, the processing device 40 flattens the outer side surfaces 17 and 27 and the stepped surface 28 by bringing an outer peripheral surface 46 of an annular polishing whetstone 45, which is rotated by a spindle 44 of a processing unit 43 about an axis parallel to the holding surface 42, into contact with the stepped surface 28, and bringing an end surface 47 of the polishing whetstone 45 flat in a direction perpendicular to the axis of the spindle 44 into contact with the outer side surfaces 17 and 27. The polishing whetstone 45 is softer than the whetstone of the cutting edge 36 of the cutting blade 35 and includes a whetstone smaller than the whetstone of the cutting edge 36 of the cutting blade 35. Thus, in the embodiment, in the flattening step 102, the outer side surfaces 17 and 27 and the stepped surface 28 are flattened to flatten the peripheral edge portion on the front surface 22 side of the support wafer 20.

Alternatively, in the present invention, in the flattening step 102, as illustrated in FIG. 7, the processing device 40 may flatten the outer side surfaces 17 and 27 and the stepped surface 28 by bringing the outer peripheral surface 46 of the annular polishing whetstone 45, which is rotated by the spindle 44 of the processing unit 43 about the axis perpendicular to the holding surface 42, into contact with the end portions of the outer side surface 27 and the outer side surface 17 close to the support wafer 20, and bringing the end surface 47 of the polishing whetstone 45 flat in the direction perpendicular to the axis of the spindle 44 into contact with the stepped surface 28.

### Protective Film Forming Step

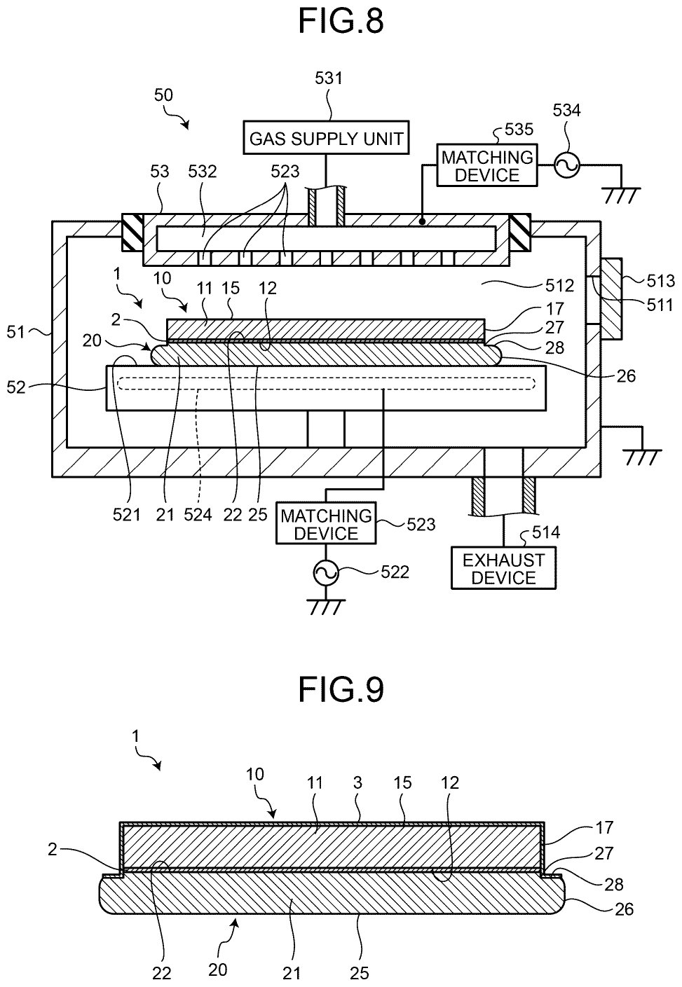

FIG. 8 is a side view schematically illustrating the protective film forming step of the method for processing a workpiece illustrated in FIG. 3 in a partial cross section. FIG. 9 is a cross-sectional view schematically illustrating the workpiece after the protective film forming step of the method for processing a workpiece illustrated in FIG. 3. The protective film forming step 103 is a step of forming a protective film 3 on the peripheral edge portion of the front surface 22 of the support wafer 20 exposed by the trimming step 101 after the trimming step 101.

In the embodiment, in the protective film forming step 103, in a plasma device 50 illustrated in FIG. 8, the workpiece 1 is carried into a processing space 512 inside a chamber 51 through an opening 511 by a conveyance unit (not illustrated), and the back surface 25 side of the support wafer 20 of the workpiece 1 is placed on a holding surface 521 of a holding table 52. In the embodiment, in the protective film forming step 103, the plasma device 50 applies high-frequency power from a high-frequency power source 522 to an electrode 524 in the holding table 52 via a matching device 523 to generate a dielectric polarization phenomenon between the holding surface 521 and the workpiece 1, and adsorb and hold the workpiece 1 on the holding surface 521 using an electrostatic adsorption force due to the polarization of charges.

In the embodiment, in the protective film forming step 103, the plasma device 50 closes the opening 511 using a gate 513 to keep the processing space 512 in the chamber 51 airtight, and decompresses the processing space 512 to a predetermined pressure using an exhaust device 514. In the embodiment, in the protective film forming step 103, the plasma device 50 supplies protective film gas from a gas supply unit 531 to a gas diffusion space 532 inside a gas ejection head 53 functioning as an upper electrode, and ejects the protective film gas from a gas ejection port 533 of the gas ejection head 53 toward the holding table 52, that is, the workpiece 1.

In the embodiment, in the protective film forming step 103, the plasma device 50 applies high-frequency power from a high-frequency power source 534 to the gas ejection head 53 via a matching device 535, and further applies high-frequency power from the high-frequency power source 522 to the electrode 524 in the holding table 52 via the matching device 523 to convert the protective film gas into plasma, and deposit the protective film gas converted into plasma on the back surface 15 and the outer side surface 17 of the wafer 10 and the outer side surface 27 and the stepped surface 28 of the support wafer 20, thereby forming the protective film 3 illustrated in FIG. 9 thereon. Thus, in the embodiment, in the protective film forming step 103, as illustrated in FIG. 9, the protective film 3 is also formed on the outer side surface 17 of the wafer 10 of the workpiece 1.

The protective film 3 has corrosion resistance to a chemical liquid 74 (illustrated in FIG. 12) used in the etching step 105, and is made of SiO2 or SiN. In the protective film forming step 103, although the protective film 3 is formed by chemical vapor deposition (CVD) in the embodiment, the protective film 3 may be formed by physical vapor deposition (PVD) in the present invention.

### Grinding Step

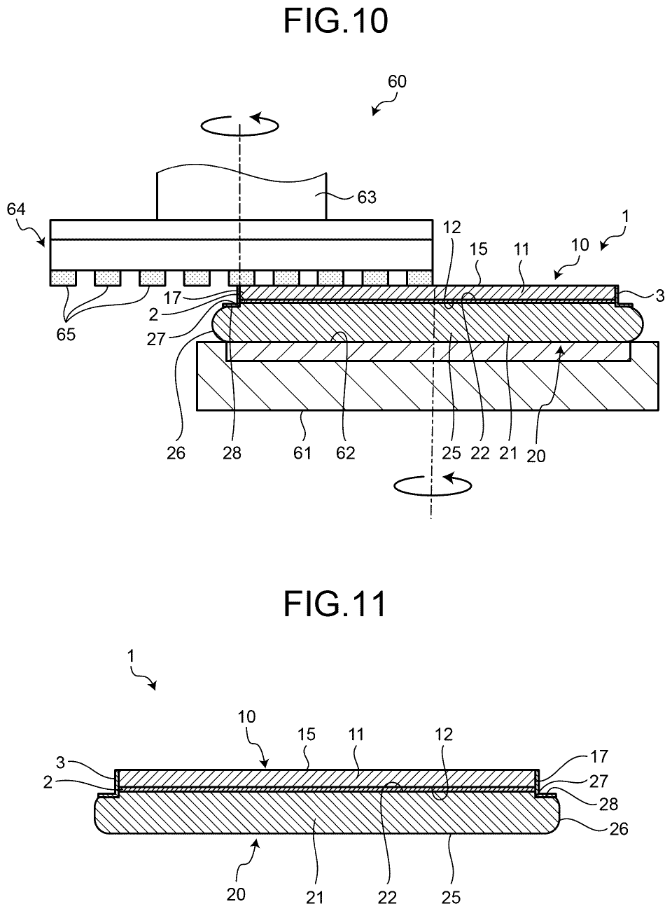

FIG. 10 is a side view schematically illustrating the grinding step of the method for processing a workpiece illustrated in FIG. 3 in a partial cross section. FIG. 11 is a cross-sectional view schematically illustrating the workpiece after the grinding step of the method for processing a workpiece illustrated in FIG. 3. The grinding step 104 is a step of grinding the workpiece 1 on the wafer 10 side to thin the wafer 10 before the etching step 105.

In the embodiment, in the grinding step 104, a grinding device 60 illustrated in FIG. 10 sucks and holds the back surface 25 side of the support wafer 20 of the workpiece 1 on a holding surface 62 of a holding table 61, and a grinding wheel 64 is rotated about an axis perpendicular to the holding surface 62 by a spindle 63, while the holding table 61 is rotated about the axis perpendicular to the holding surface 62. As illustrated in FIG. 10, while rotating the grinding wheel 64 and the holding table 61 about the axis, the grinding device 60 brings a grinding whetstone 65 into contact with the back surface 15 of the wafer 10 of the workpiece 1 to approach the holding table 61 at a predetermined feed speed, thereby grinding the back surface 15 of the wafer 10 of the workpiece 1 with the grinding whetstone 65. In the embodiment, in the grinding step 104, as illustrated in FIG. 11, the grinding device 60 grinds the wafer 10 to remove the protective film 3 from the back surface 15 of the wafer 10 and expose the substrate 11 of the wafer 10.

### Etching Step

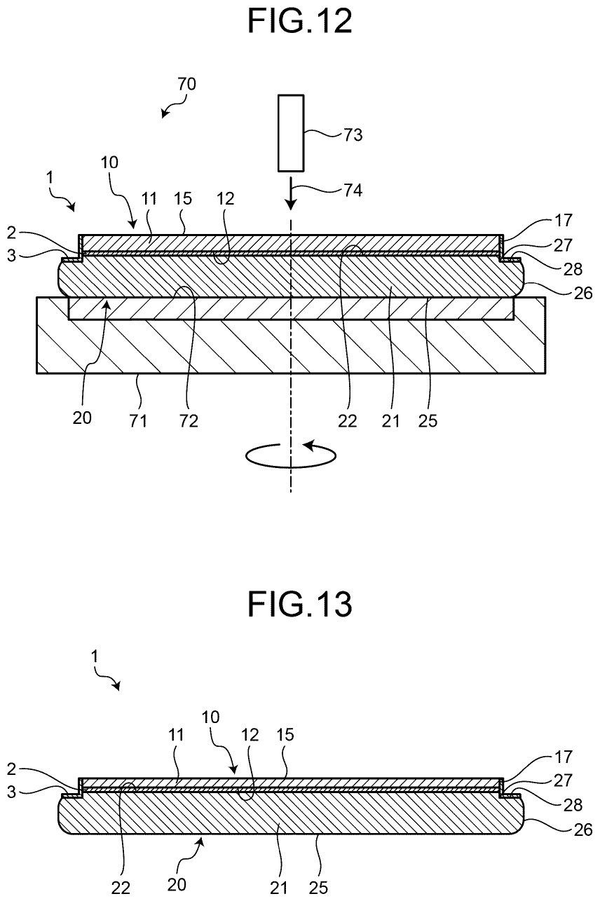

FIG. 12 is a side view schematically illustrating the etching step of the method for processing a workpiece illustrated in FIG. 3 in a partial cross section. FIG. 13 is a cross-sectional view schematically illustrating the workpiece after the etching step of the method for processing a workpiece illustrated in FIG. 3. The etching step 105 is a step of etching the workpiece 1 on the wafer 10 side after the protective film forming step 103.

In the embodiment, in the etching step 105, an etching device 70 illustrated in FIG. 12 sucks and holds the back surface 25 of the support wafer 20 of the workpiece 1 on a holding surface 72 of a spinner table 71. In the embodiment, in the etching step 105, as illustrated in FIG. 12, the etching device 70 supplies the chemical liquid 74 (hydrofluoric nitric acid in the embodiment) having corrosiveness to the substrate 11 of the wafer 10 from a nozzle 73 onto the center of the back surface 15 of the wafer 10 of the workpiece 1, while rotating the spinner table 71 about an axis perpendicular to the holding surface 72.

Then, the chemical liquid 74 flows toward the outer periphery of the workpiece 1 due to the centrifugal force caused by the rotation of the spinner table 71, and corrodes the entire back surface 15 of the wafer 10 of the workpiece 1. In the embodiment, in the etching step 105, as illustrated in FIG. 13, the etching device 70 performs so-called wet etching on the back surface 15 of the wafer 10 to thin the wafer 10 to a predetermined thickness, while releasing the internal stress of the wafer 10 of the workpiece 1 that has occurred in the grinding step 104, removing the damage to the back surface 15, and removing particles from the back surface 15.

As described above, since the protective film forming step 103 is performed after the trimming step 101 and before the etching step 105 to form the protective film 3 on the stepped surface 28 in the peripheral edge portion on the front surface 22 side of the support wafer 20 exposed by the trimming step 101, the method for processing a workpiece according to the embodiment is advantageous in that the peripheral edge portion of the support wafer 20 can be prevented from being etched in the etching step 105.

In addition, since the protective film 3 is also formed on the outer side surfaces 17 and 27 of the wafers 10 and 20 in the protective film forming step 103, the method for processing a workpiece according to the embodiment is advantageous in that the peripheral edge portion of the support wafer 20 can be prevented from being etched in the etching step 105.

In addition, since the grinding step 104 is performed before the etching step 105 to grind the back surface 15 of the wafer 10 of the workpiece 1, the method for processing a workpiece according to the embodiment is advantageous in that the back surface 15 of the wafer 10 can be exposed before the etching step 105 for etching.

In addition, since the flattening step 102 is performed before the protective film forming step 103 to flatten the stepped surface 28 of the support wafer 20 and the outer side surfaces 17 and 27 of the wafers 10 and 20, the method for processing a workpiece according to the embodiment is advantageous in that the protective film 3 can be formed in the protective film forming step 103.

The present invention is not limited to the above-described embodiment. That is, various modifications can be made without departing from the gist of the present invention. In the present invention, in the trimming step 101, the peripheral edge portion may be removed by stealth dicing in which a laser beam having a wavelength that is transparent to the wafer 10 is irradiated, or the peripheral edge portion may be removed by laser ablation of applying a laser beam having a wavelength that is absorbent to the wafer 10, instead of trimming using the cutting blade 35 as in the embodiment.

Further, in the present invention, in the etching step 105, plasma etching using gas converted into plasma may be performed. In this case, the protective film 3 may be formed by applying a liquid water-soluble resin (e.g., HogoMax (registered trademark) manufactured by DISCO Corporation) such as polyvinyl alcohol (PVA) or polyvinyl pyrrolidone (PVP) and drying the liquid water-soluble resin.

In the present invention, the etching step 105 may be performed after the protective film forming step 103 without performing the grinding step 104.

According to the present disclosure, the peripheral edge portion of the support wafer can be prevented from being etched.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method for processing a workpiece obtained by bonding one surface of a wafer and one surface of a support wafer via a bonding layer, the method comprising:
trimming the workpiece, the trimming including removing a peripheral edge portion of the wafer of the workpiece in a thickness direction and removing a part of a peripheral edge portion of the one surface of the support wafer in the thickness direction;
after trimming the workpiece, forming a protective film on the peripheral edge of the one surface of the support wafer exposed by trimming the workpiece; and
etching the workpiece on a wafer side after forming the protective film.

2. The method for processing a workpiece according to claim 1, wherein forming the protective film includes forming a protective film also on a side surface of the wafer of the workpiece.

3. The method for processing a workpiece according to claim 1, further comprising, before etching the workpiece, grinding the workpiece on the wafer side to thin the wafer.

4. The method for processing a workpiece according to claim 1, wherein trimming the workpiece includes causing a cutting blade to cut into the peripheral edge portion of the wafer, so as to remove the peripheral edge portion of the wafer and remove a part of the peripheral edge portion of the one surface of the support wafer.

5. The method for processing a workpiece according to claim 1, further comprising, before forming the protective film, flattening the peripheral edge portion of the one surface of the support wafer exposed by trimming the workpiece.
